(19) United States
(12) Patent Application Publication
(10) Pub. No.: US 2010/0227479 A1
(43) Pub. Date: Sep. 9, 2010

(54) Semiconductor device and associated methods of manufacture

(75) Inventors: Sunjung Kim, Yongin-si (KR); JongCheol Lee, Seoul (KR); Bonyoung Koo, Suwon-si (KR); Wansik Hwang, Hwaseong-si (KR); Joon Gon Lee, Seoul (KR); JungHyeon Kim, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/660,793

(22) Filed: Mar. 4, 2010

(30) Foreign Application Priority Data
Mar. 9, 2009 (KR) 10-2009-0019950

(51) Int. Cl. H01L 21/3105

(52) U.S. Cl. 438/778; 257/E21.241

(57) ABSTRACT

Provided are a semiconductor device and a method of fabricating the same. The method includes forming a metal nitride layer and a metal oxide layer on a semiconductor substrate to be in contact with each other, and annealing the substrate including the metal nitride layer and the metal oxide layer to form a metal oxynitride layer.

### CROSS-REFERENCE TO RELATED APPLICATIONS

This U.S. non-provisional patent application claims priority under 35 U.S.C. § 119 of Korean Patent Application No. 10-2009-0019950, filed in the Korean Intellectual

Property Office on Mar. 9, 2009, the entire contents of which are hereby incorporated by reference.

### BACKGROUND

The present inventive concept herein relates to semiconductor devices and methods of fabricating the same.

Semiconductor devices are being widely adopted in various electronic devices for their characteristics such as multi-functionality, miniaturization and/or low power consumption. Semiconductors device may include various kinds of material layers. For instance, a semiconductor device may include a conductive layer used as an electrode or an interconnection and a dielectric layer used as an insulating layer.

In a semiconductor device, material layers made of different elements may be disposed adjacent to each other or in contact with each other. In this case, different elements may diffuse or migrate between the material layers to cause various problems such as degradation in characteristics of the material layers. When the characteristics of the material layers are degraded or lost, the reliability of a semiconductor device including such material layers may be lowered, or characteristics thereof may be degraded. Accordingly, much research has been focused on a variety of material layers constituting a semiconductor device.

### SUMMARY

Embodiments of the inventive concept provide a method of fabricating a semiconductor device and a semiconductor device fabricated thereby.

According to a first aspect, the inventive concept is directed to a method of manufacturing a semiconductor device. The method may include forming a metal nitride layer and a metal oxide layer on a semiconductor substrate to be in contact with each other, and annealing the substrate including the metal nitride layer and the metal oxide layer to form a metal oxynitride layer.

In one embodiment, forming a metal nitride layer and a metal oxide layer comprises forming the metal nitride layer on the semiconductor substrate; and forming the metal oxide layer on the metal nitride layer.

In one embodiment, the method further comprises, before annealing the substrate, forming a second metal nitride layer on the metal oxide layer. The metal oxynitride layer is formed by reacting the metal nitride layer, the metal oxide layer, and the second metal nitride layer with one another.

In one embodiment, forming a metal nitride layer and a metal oxide layer comprises forming the metal oxide layer on the semiconductor substrate; and forming the metal nitride layer on the metal oxide layer.

In one embodiment, the metal nitride layer comprises metal elements of the same kind as that in the metal oxide layer.

In one embodiment, the method further comprises forming a material layer on the semiconductor substrate to be in contact with one surface of the metal oxynitride layer.

In one embodiment, the metal oxynitride layer includes a nitrogen peak region adjacent to a surface that is in contact with the material layer.

According to another aspect, the inventive concept is directed to a semiconductor device. The semiconductor device may include a material layer disposed on a semiconductor substrate and a metal oxynitride layer having a first surface that is contact with the material layer and a second surface that is opposite to the first surface. The metal oxynitride includes a nitrogen peak region adjacent to the first surface.

In one embodiment, the nitrogen density of the metal oxynitride layer decreases from the nitrogen peak region to the second surface.

In one embodiment, the method further comprises a second material layer that is in contact with the second surface. The metal oxynitride further includes a nitrogen peak region adjacent to the second surface, and a central region of the metal oxynitride layer between the nitrogen peak region adjacent to the first surface and the nitrogen peak region adjacent to the second surface has a lower nitrogen density than the nitrogen densities at the nitrogen peak regions.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIGS. 1A through 1E are cross-sectional views illustrating a method of fabricating a semiconductor device according to one exemplary embodiment of the present inventive concept.

FIG. 1F is a cross-sectional view illustrating s a semiconductor device according to the one exemplary embodiment of the present inventive concept.

FIGS. 2A through 2E are cross-sectional views illustrating a method of fabricating a semiconductor device according to another exemplary embodiment of the present inventive concept.

FIG. 2F is a cross-sectional view illustrating a semiconductor device according to the another exemplary embodiment of the present inventive concept.

FIG. 3A is a cross-sectional view illustrating a method of fabricating a semiconductor device according to still another exemplary embodiment of the present inventive concept_{;}

FIG. 3B is a cross-sectional view illustrating a semiconductor device according to the still another exemplary embodiment of the present inventive concept.

FIG. 4A is a graph showing a nitrogen density distribution along line I-I′ in FIG. 1B, which represents nitrogen density distribution characteristics of the metal oxynitride layer formed by an annealing process.

FIG. 4B is a graph showing a nitrogen density distribution along lone II-IP in FIG. 2D, which represents nitrogen density distribution characteristics of the metal oxynitride layer formed by an annealing process.

FIG. 5 is a block diagram of a memory system employing a semiconductor device according to exemplary embodiments of the present inventive concept.

### DETAILED DESCRIPTION OF THE EMBODIMENTS

Preferred embodiments of the inventive concept will be described below in more detail with reference to the accompanying drawings. The embodiments of the present inventive concept may, however, be embodied in different forms and should not be construed as limited to the embodiments set forth herein. Rather, these embodiments are provided so that this description will be thorough and complete, and will fully convey the inventive concept to those skilled in the art. Because embodiments disclosed herein are preferred embodiments of the inventive concept, appearing reference numerals are not necessarily indicative of order and therefore not limited by the order as they appear. In the drawings, the sizes and relative sizes of layers and regions are exaggerated for clarity. It will be understood that when an element such as a layer, region or substrate is referred to as being “on” another element, it can be directly on the other element or intervening elements may also be present. As used herein, the term “and/or” includes any and all combinations of one or more of the associated listed items.

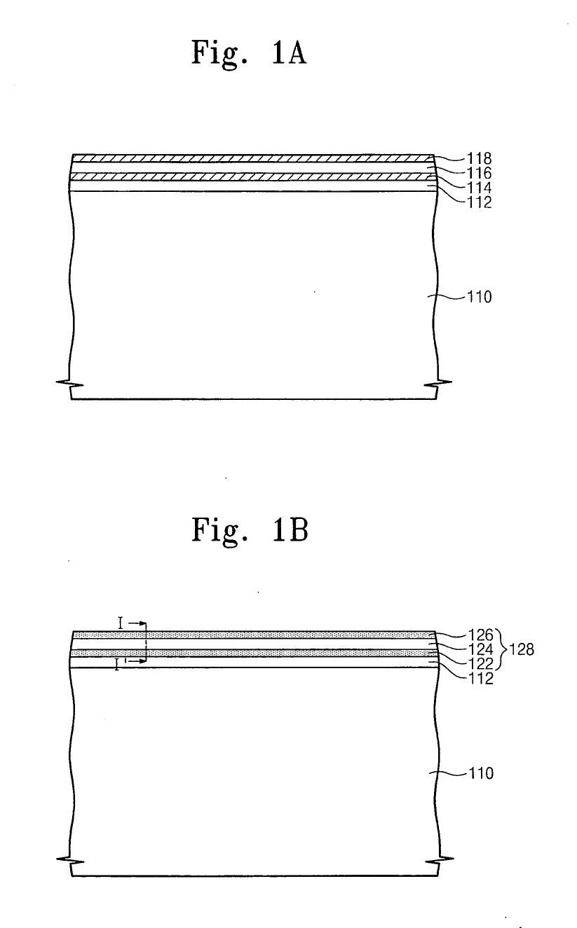

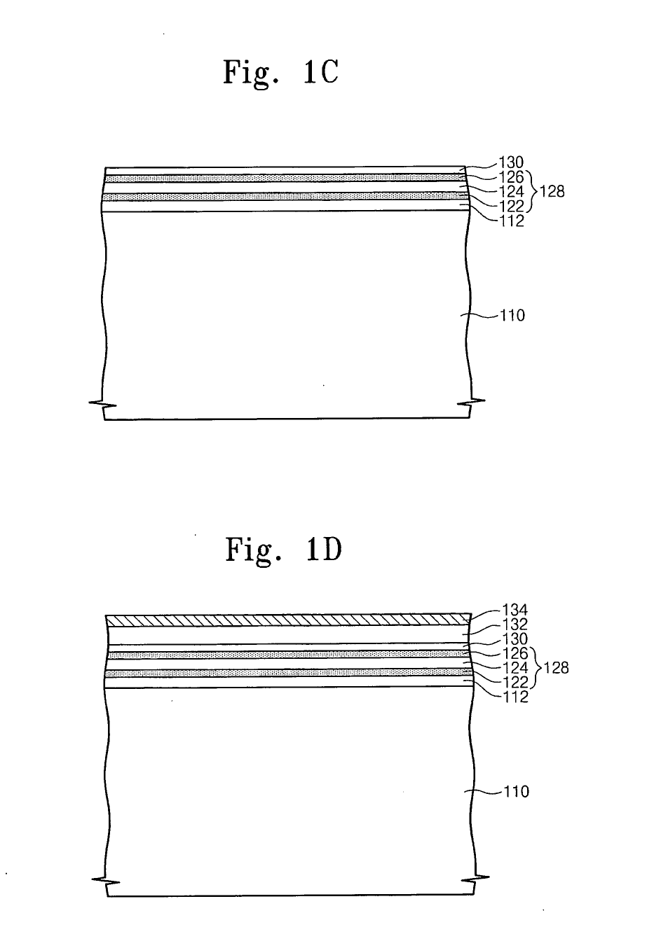

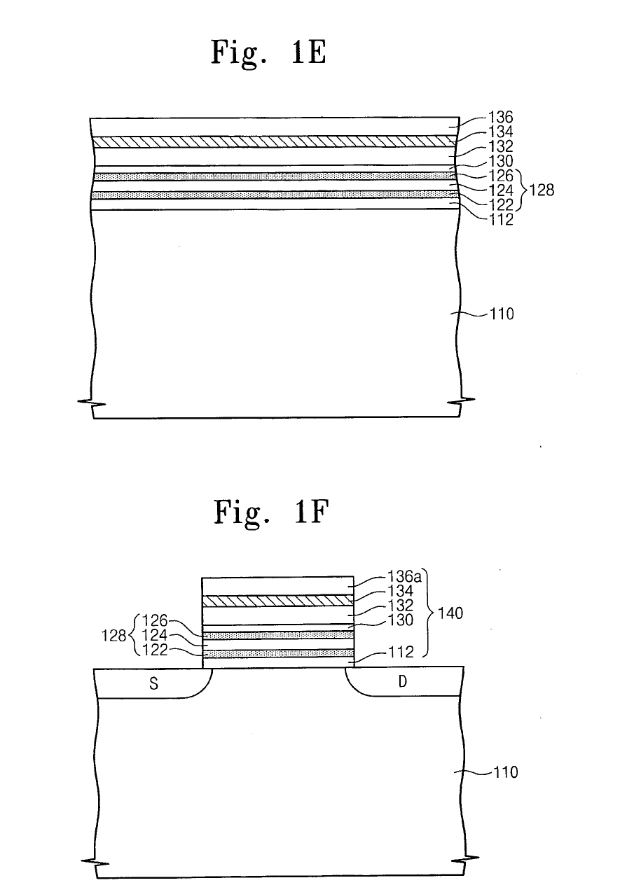

FIGS. 1A through 1E are cross-sectional views illustrating a method of manufacture of a semiconductor device according to one exemplary embodiment of the present inventive concept. FIG. 1F is a cross-sectional view illustrating a semiconductor device according to this one exemplary embodiment of the present inventive concept.

Referring FIG. 1A, a first dielectric layer 112 may be formed on a semiconductor substrate 110. The first dielectric layer 112 may comprise a silicon oxide layer formed by chemical vapor deposition (CVD) or thermal oxidation. A first metal nitride layer 114 may be formed on the first dielectric layer 112, and a metal oxide layer 116 may be formed on the metal nitride layer 114. The metal oxide layer 116 may be in contact with the upper surface of the first metal nitride layer 114. A second metal nitride layer 118 may be formed on the metal oxide layer 116. The second metal nitride layer 118 may be in contact with the upper surface of the metal oxide layer 116. The metal oxide layer 116 may have a high dielectric constant.

The first metal nitride layer 114 and the second metal nitride layer 118 may be formed by atomic layer deposition (ALD), physical vapor deposition (PVD) or chemical vapor deposition (CVD). The metal oxide layer 116 may also be formed by atomic layer deposition (ALD), physical vapor deposition (PVD) or chemical vapor deposition (CVD). The first metal nitride layer 114 and the second metal nitride layer 118 may include a metal element of the same kind as that in the metal oxide layer 116. For example, the first metal nitride 114, the metal oxide layer 116, and the second metal nitride layer 118 may include one of the metals such as aluminum (Al), Hafnium (Hf), Zirconium (Zr), Tantalum (Ta), and Titanium (Ti).

Referring to FIG. 1B, a metal oxynitride layer 128 may be formed by annealing the first and the second metal nitride layers 114, 118 and the metal oxide layer 116 on the semiconductor substrate 110. The annealing process may be performed at a process temperature of 850-1100° C. The first dielectric layer 112 may be in contact with the bottom surface of the metal oxynitride layer 128.

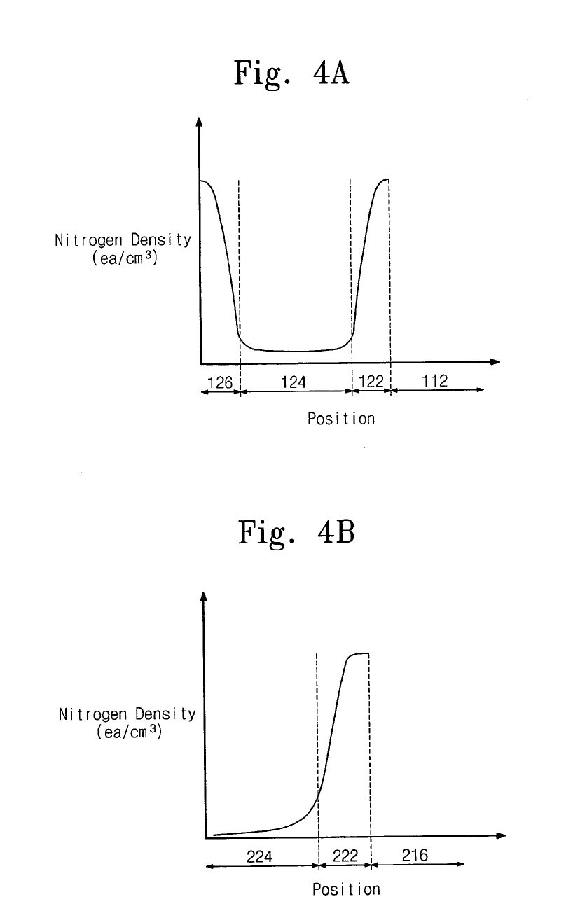

During the annealing process, extra oxygen atoms within the metal oxide layer 116 may migrate into the metal nitride layers 114 and 118 to oxidize the metal nitride layers 114 and 118, and likewise a portion of nitrogen atoms within the metal nitride layers 114 and 118 may migrate into the metal oxide layer 116. The metal oxynitride layer 128 formed by the annealing process may include a nitrogen peak region. The nitrogen peak region is a region where nitrogen is at its peak density. The nitrogen density within the metal oxynitride layer 128 will be described herein below with reference to a graph in FIG. 4A.

FIG. 4A is a graph showing nitrogen density distribution along line I-I′ in FIG. 1B, which represent nitrogen density distribution characteristic of the metal oxynitride layer 128 formed by the annealing process. In FIG. 4A, the horizontal axis represents position and the vertical axis represents nitrogen density.

Referring to FIG. 1B and FIG. 4A, the metal oxynitride layer 128 may comprise a lower portion 122, a central portion 124, and an upper portion 126 that are stacked in the order listed. The lower portion 122 of the metal oxynitride layer 128 may be formed when the first metal nitride layer 114 is oxidized by extra oxygen within the metal oxide layer 116. Accordingly, the lower portion 122 of the metal oxynitride layer 128 may include a nitrogen peak region. The upper portion 126 of the metal oxynitride layer 128 may be formed when the second metal nitride layer 118 is oxidized by extra oxygen within the metal oxide layer 116. Accordingly, the upper portion 126 of the metal oxynitride layer 128 may include a nitrogen peak region. The central portion 124 of the metal oxynitride layer 128 may have lower nitrogen density than the nitrogen peak regions.

The lower portion 122 of the metal oxynitride layer 128 including a nitrogen peak region may function to suppress the diffusion of atoms. Accordingly, metal atoms within the metal oxynitride layer 128 may be prevented from diffusing and/or migrating to a material layer of a different kind (e.g., the first dielectric layer 112) that is in contact with the lower portion 122 of the metal oxynitride layer 128. Likewise, elements within a material layer of a different kind (e.g., the first dielectric layer 112) that is in contact with the lower portion 122 of the metal oxynitride layer 128 may also be prevented from diffusing or migrating to the metal oxynitride layer 128. As a result, the metal oxynitride layer 128 and the material layer (e.g., the first dielectric layer 112) that is in contact with the bottom portion 122 of the metal oxynitride layer 128 may have superior reliability.

For instance, in the case that the first dielectric layer 112 is formed of a silicon oxide layer, interdiffusion of metal and silicon between the first dielectric layer 112 and the metal oxynitride layer 128 may be minimized due to the lower portion 122 of the metal oxynitride 128 including the nitrogen peak region.

According to another embodiment of the present inventive concept, one of the first and second metal nitride layers 114 and 118 may be omitted. In this case, one metal nitride layer 114 or 118 may react to the metal oxide layer 116 during the annealing process to form the metal oxynitride layer 128. The metal oxynitride layer 128 may include one nitrogen peak region. For instance, in the case that the first metal nitride layer 114 is omitted and the second metal nitride layer 118 is formed, the upper portion 126 of the metal oxynitride layer 128 may include the nitrogen peak region while the lower portion 122 of the metal oxynitride layer 128 may have a lower nitrogen density than the upper portion 126. On the other hand, in the case that the first metal nitride layer 114 is formed and the second metal nitride layer 118 is omitted, the lower portion 122 of the metal oxynitride layer 128 may include the nitrogen peak region while the upper portion 126 of the metal oxynitride layer 128 may have a lower nitrogen density than the lower portion 122.

The first and the second metal nitride layers 114 and 118 are desirably formed to a thickness of about 30A or less. Accordingly, the first and the second metal nitride layers 114 and 118 may be sufficiently oxidized by the annealing process.

Referring to FIG. 1C, the second dielectric layer 130 may be formed on the metal oxynitride layer 128 formed by the annealing process. The second dielectric layer 130 may comprise a silicon oxide layer formed by chemical vapor deposition (CVD). As described above, the upper portion 126 of the metal oxynitride layer 128 may include a nitrogen peak region. Accordingly, the upper portion 126 of the metal oxynitride 128 may function to minimize the diffusion of elements. As a result, metal atoms within the metal oxynitride 128 may be prevented from diffusing and/or migrating to a material layer of a different kind (for example, the second dielectric layer 130) that is in contact with the upper portion 126 of the metal oxynitride layer 128.

According to another embodiment of the present inventive concept, one of the first and second dielectric layers 112 and 130 may be omitted. For the convenience of description, desctiption will now be made for the case where both the first and the second dielectric layers 112 and 130 are formed.

Referring to FIG. 1D, a charge storage layer 132 may be formed on the second dielectric layer 130. The charge storage layer 132 may include a charge trap layer, which contains traps being capable of storing charges. For instance, the charge trap layer may include at least one selected from the group consisting of silicon nitride, metal nitride, metal oxynitride, metal silicon oxide, metal silicon oxynitride, and nano dots. Alternatively, the charge storage layer 132 may include a floating gate layer formed of group IV-A elements. For instance, the floating gate layer may include at least one selected from the group consisting of undoped silicon, doped silicon, undoped germanium, doped germanium, undoped silicon-germanium and doped silicon-germanium.

A blocking dielectric layer 134 may be formed on the charge storage layer 132. The blocking dielectric layer 134 may comprise a metal oxide layer having a high dielectric constant. The blocking dielectric layer 134 may be formed of a single layer or a multiple layer.

Referring to FIG. 1E, a control gate conductive layer 136 may be formed on the blocking dielectric layer 134. The control gate conductive layer 136 may include at least one selected from the group consisting of conductive metal nitride (e.g., titanium nitride or tantalum nitride), polysilicon, metal silicide (e.g., cobalt silicide or nickel silicide), and metal.

A gate pattern 140 may be formed by patterning at least the control gate conductive layer 136 in FIG. 1F. The gate pattern 140 may comprise a control gate electrode 136a on the blocking dielectric layer 134. In the case that the charge storage layer 132 includes a charge trap layer, the blocking dielectric layer 134 or the second dielectric layer 130 may be used as an etch-stop layer while patterning the gate pattern 140. Alternatively, in the case that the charge storage layer 132 is formed by a floating gate layer formed of group IV-A elements, the second dielectric layer 130 may be used as an etch-stop layer while patterning the gate pattern 140. Accordingly, floating gates may be separated from each other.

Source S and drain D regions in FIG. 1F may be formed on both sides of the gate pattern 140 on the semiconductor substrate 110. The source region S and the drain region D may be regions doped with dopants. Alternatively, the source regions S and the drain region D may be inverted layers formed by an operation voltage applied to the control gate electrode 136a. The inverted layers may be formed by a fringe field that is established at the control gate electrode 136a due to the operation voltage.

A semiconductor device according to embodiments of the present inventive concept will be described with reference to FIG. 1F.

Referring to FIG. 1F, a gate pattern 140 may be disposed on a semiconductor substrate 110, and a source region S and a drain region D may be disposed on both sides of the gate pattern 140 on the semiconductor substrate 110. As described aboveg, the source and drain regions S and D may be either regions doped with dopants or inverted layers. The gate pattern 140 may comprise a first dielectric layer 112, a metal oxynitride layer 128, a second dielectric layer 130, a charge storage layer 132, a blocking dielectric layer 134 and a control gate electrode 136a. The control gate electrode 136a may be disposed on the semiconductor substrate 110, and the charge storage layer 132 may be interposed between the control gate electrode 136a and the semiconductor substrate 110. The metal oxynitride layer 128 may be interposed between the charge storage layer 132 and the semiconductor substrate 110, and the first dielectric layer 112 may be interposed between the metal oxynitride layer 128 and the semiconductor substrate 110. The second dielectric layer 130 may be interposed between the metal oxynitride layer 128 and the charge storage layer 132. The first dielectric layer 112, the metal oxynitride layer 128 and the second dielectric layer 130 which are interposed between the charge storage layer 132 and the semiconductor substrate 110 may comprise a tunneling dielectric layer. The gate pattern 140, source region S and drain region D may comprise a memory cell. The memory cell may have nonvolatile characteristics, i.e., may retain its stored data even when its power supply is interrupted. As described above, both the first and the second dielectric layer 112 and 130 may exist or either one of them may be omitted.

The metal oxynitride layer 128 included in the tunneling dielectric layer may have a higher dielectric constant than the first dielectric layer 112 and/or the second dielectric layer 130. Accordingly, under the same thickness, an equivalent oxide thickness of the metal oxynitride layer 128 may be smaller than that of the first dielectric layer 112 and/or the second dielectric layer 130. The metal oxynitride 128 makes it possible to achieve a tunneling dielectric layer which is physically thick while having a small equivalent oxide thickness. As a result, leakage of charges stored in the charge storage layer 132 to the semiconductor substrate 110 may be minimized, and data retention characteristics of the memory cell and reliability of data may be improved.

In addition, the metal oxynitride layer 128 may have a smaller energy band gap than the first dielectric layer 112 and/or the second dielectric layer 130. Particularly, the metal oxynitride 128 may have a higher electron affinity than the first dielectric layer 112 and/or the second dielectric layer 130. Accordingly, the probability that charges tunnel through the tunneling dielectric layer may increase during a programming operation. As a result, program efficiency of the memory cell may be improved.

Further, as mentioned above, the metal oxynitride layer 128 may comprise a lower portion 122 and/or an upper portion 126, which include a nitrogen peak region(s). Accordingly, metal atoms within the metal oxynitride layer 128 may be prevented from diffusing and/or migrating to an external material layer. Elements within the external material layer may also be prevented from diffusing and/or migrating to the metal oxynitride layer 128. The external material layer may be the first dielectric layer 112 and/or the second dielectric layer 130, both of which or either one of which is in contact with the metal oxynitride layer 128. Aternatively, in the case that the second dielectric layer 130 is omitted, the external material layer may serve as the charge storage layer 132. As a result, the metal oxynitride 128 may have superior reliability. Accordingly, the memory cell employing the metal oxynitride layer 128 may also have superior reliability.

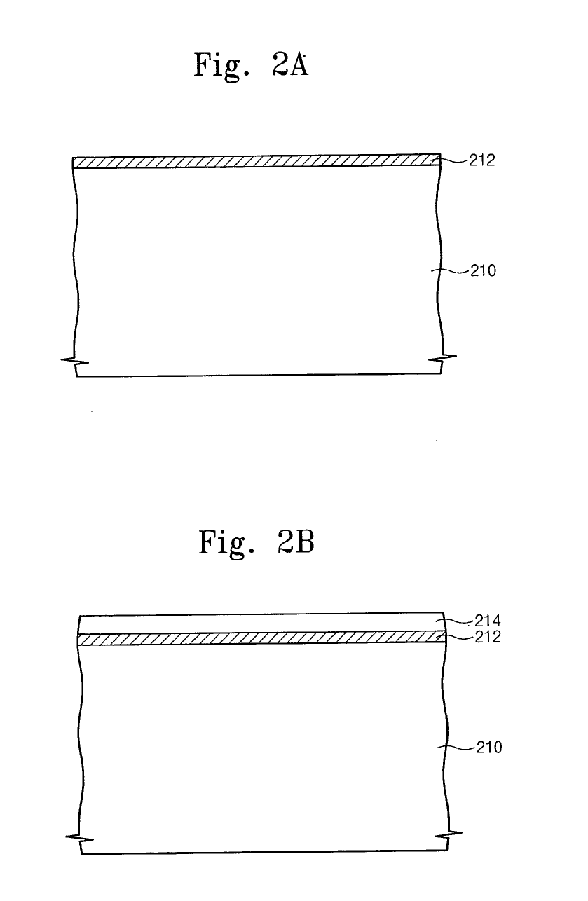

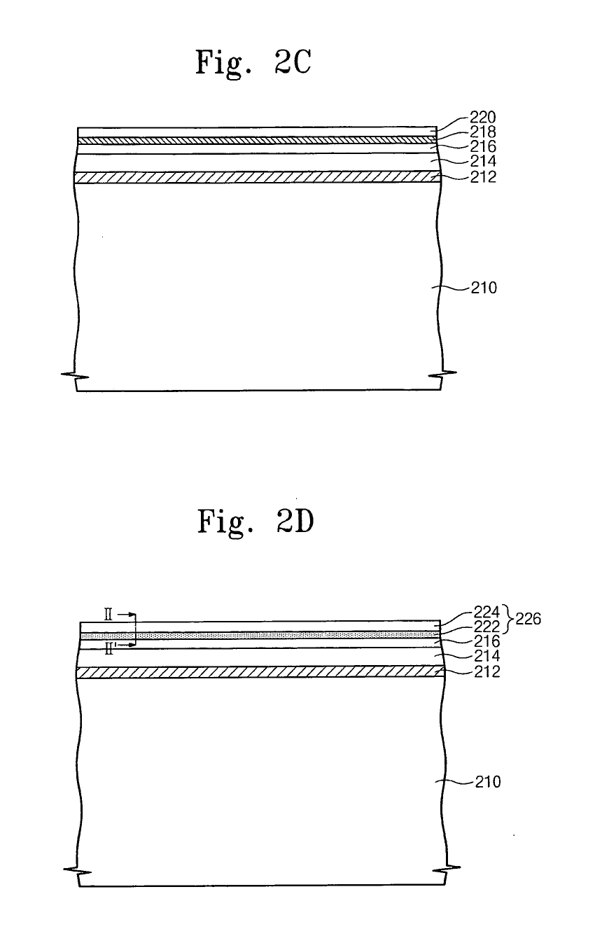

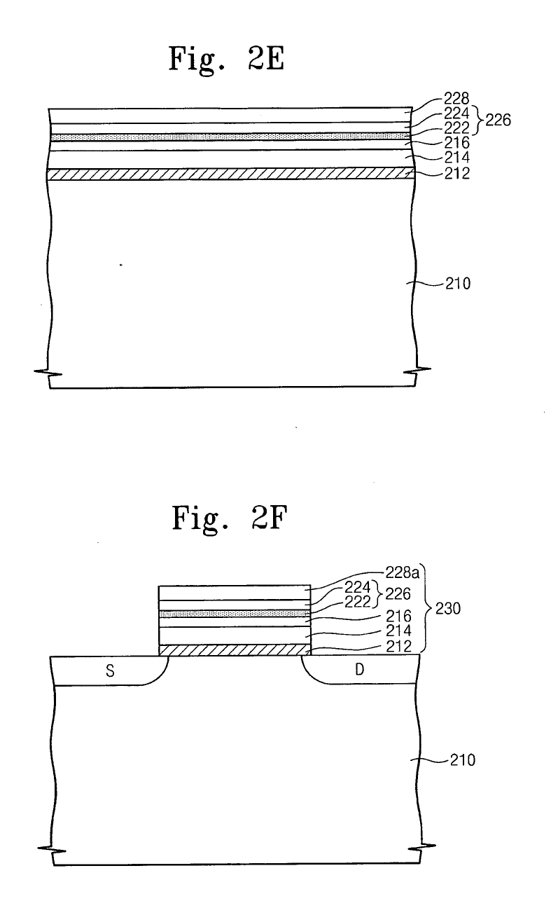

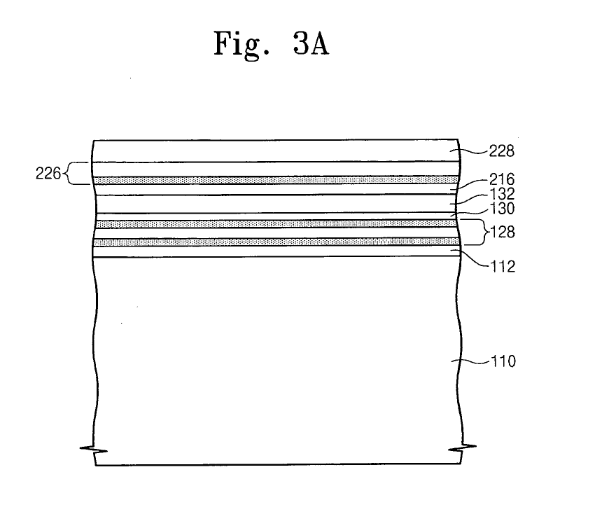

FIGS. 2A through 2E are cross-sectional views illustrating a method of manufacture of a semiconductor device according to another exemplary embodiment of the present inventive concept. FIG. 2F is a cross-sectional view illustrating a semiconductor device according to this other exemplary embodiment of the present inventive concept;

Referring to FIG. 2A, a tunneling dielectric layer 212 may be formed on a semiconductor substrate 210. The tunneling dielectric layer 212 may comprise a silicon oxide layer formed by chemical vapor deposition (CVD) or thermal oxidation. The tunneling dielectric layer 212 may be formed by sequentially stacking a silicon oxide layer, a metal oxide layer, and a silicon oxide layer.

Referring to FIG. 2B, a charge storage layer 214 may be formed on the tunneling layer 212. The charge storage layer 214 may include a charge trap, which contains traps being capable of storing charges. For instance, the charge trap layer may include at least one selected from the group consisting of silicon nitride, metal nitride, metal oxynitride, metal silicon oxide, metal silicon oxynitride, and nano dots. Alternatively, the charge storage layer 214 may include a floating gate layer formed of group IV-A elements. For instance, the floating gate layer may include at least one selected from the group consisting of silicon, doped silicon, undoped germanium, doped germanium, undoped silicon-germanium and doped silicon-germanium.

Referring to FIG. 2C, a dielectric layer 216 may be formed on the charge storage layer 214. The dielectric layer 216 may comprise a silicon oxide layer formed by chemical vapor deposition (CVD). After forming a metal nitride layer 218 on the dielectric layer 216, a metal oxide layer 220 may be formed on the metal nitride layer 218. The metal oxide layer 220 may be in contact with the upper surface of the metal nitride layer 218. A second metal nitride layer may be additionally formed on the metal oxide layer 220. In this case, the second metal oxide layer may be in contact with the upper surface of the metal oxide layer 220. The metal oxide layer 220 has a high dielectric constant.

The metal nitride layer 218 may be formed by atomic layer deposition (ALD), physical vapor deposition (PVD) or chemical vapor deposition (CVD). The metal oxide layer 220 may also be formed by atomic layer deposition (ALD), physical vapor deposition (PVD) or chemical vapor deposition (CVD). The metal nitride layer 218 may include metal elements of the same kind as those in the metal oxide layer 220. For example, the metal nitride layer 218 and the metal oxide layer 220 may include one selected from the group consisting of aluminum (Al), Hafnium (Hf), Zirconium (Zr), Tantalum (Ta), and Titanium (Ti).

Referring to FIG. 2D, a metal oxynitride layer 226 can be formed by annealing the metal nitride layer 218 and the metal oxide layer 220. The annealing process may be performed at a process temperature of 85˜1100° C. The dielectric layer 216 may be in contact with the bottom surface of the metal oxynitride layer 226.

During the annealing process, extra oxygen atoms within the metal oxide layer 220 may migrate to the metal nitride layer 218 to oxidize the metal nitride layer 218. The metal oxynitride layer 226 formed by the annealing process may include a nitrogen peak region. The nitrogen peak region is a region where nitrogen is at its peak density. The nitrogen density within the metal oxynitride layer 226 will be described with reference to the graph in FIG. 4B.

FIG. 4B is a graph showing nitrogen density distribution along line II-II′ in FIG. 2D, which represent nitrogen density distribution characteristics of the metal oxynitride layer 226 formed by the heat-treatment.

Referring to FIG. 2D and FIG. 4B, the X-axis of the graph in FIG. 4B represents position and the Y-axis represent nitrogen density. The metal oxynitride layer 226 may comprise a lower portion 222 and an upper portion 224, which are sequentially stacked. The lower portion 222 of the metal oxynitride layer 226 may be formed when the metal nitride layer 218 is oxidized by extra oxygen within the metal oxide layer 220. Accordingly, a lower portion 222 of the metal oxynitride layer 226 may include a nitrogen peak region. In contrast, an upper portion 224 of the metal oxynitride layer 226 may have a lower nitrogen density than the nitrogen peak regions.

The lower portion 222 of the metal oxynitride layer 226 including a nitrogen peak region may function to prevent diffusion of atoms. Accordingly, metal atoms within the metal oxynitride layer 226 may be prevented from diffusing and/or migrating to a material layer (e.g., the dielectric layer 214) that is in contact with the lower portion 222 of the metal oxynitride layer 226. Likewise, elements within a material layer of a different kind (e.g., the dielectric layer 214) that in contact with the lower portion 222 of the metal oxynitride layer 226 may also be prevented from diffusing and/or migrating to the metal oxynitride layer 226. As a result, the metal oxynitride layer 226 and the material layer (e.g., the dielectric layer 214) that is in contact with the lower portion 222 of the metal oxynitride layer 226 may have superior reliability.

For instance, in the case that the dielectric layer 214 is formed of a silicon oxide layer, inter-diffusion of metal and silicon between the dielectric layer 214 and the metal oxynitride layer 226 may be minimized due to the lower portion 222 of the metal oxynitride layer 226 including the nitrogen peak region.

According to still another embodiment of the present inventive concept, a second metal nitride layer may be additionally formed on the metal oxide 224. In this case, the first metal nitride layer 218, the second metal nitride layer, and the metal oxide layer 220 react with one other during the annealing process to form the metal oxynitride layer 226. In this case, the metal oxynitride layer 226 may include two nitrogen peak regions. For instance, the upper and lower portions 222 of the metal oxynitride layer 226 may include a nitrogen peak region, respectively. Accordingly, the central portion of the metal oxynitride layer 226 may have a lower nitrogen density than the nitrogen peak regions.

It is desirable that the metal nitride layer 218 be formed to a thickness of about 30A or thinner. Accordingly, the second metal nitride layer 218 may be sufficiently oxidized by the annealing process.

Referring to FIG. 2E, a control gate conductive layer 228 may be formed on the metal oxynitride layer 226. The control gate conductive layer 228 may include at least one selected from the group consisting of conductive metal nitride material (e.g., titanium nitride or tantalum nitride), polysilicon, metal silicide (e.g., cobalt silicide or nickel silicide), and metal.

According to another embodiment of the present inventive concept, an additional dielectric layer may be formed on the metal oxynitride layer 226, and the control gate conductive layer 228 may be formed on the additional dielectric layer. For the convenience of description, description will be made for the case where only the dielectric layer 216 is formed.

A gate pattern 230 may be formed by patterning at least the control gate conductive layer 228 in FIG. 2F. The gate pattern 230 may comprise a control gate electrode 228a on the metal oxynitride layer 226. In the case that the charge storage layer 214 includes a charge trap layer, the metal oxynitride layer 226 or the dielectric layer 216 may be used as an etch-stop layer while patterning the gate pattern 230. Alternatively, in the case that the charge storage layer 214 is formed by a floating gate layer formed of group IV-A elements, the dielectric layer 216 may be used as an etch-stop layer while patterning the gate pattern 230. Accordingly, floating gates may be separated from each other.

Source S and drain D regions in FIG. 2F may be formed on both sides of the gate pattern 230 on the semiconductor substrate 210. The source region S and the drain region D may be regions doped with dopants. Alternatively, the source region S and the drain region D may be inverted layers formed by an operation voltage applied to the control gate electrode 228a. The inverted layers may be formed by a fringe field that is established by the control gate electrode 228a due to the operation voltage.

Next, a semiconductor device according to another embodiment of the present inventive concept will be described with reference to FIG. 2F.

Referring to FIG. 2F, a gate pattern 230 may be disposed on a semiconductor substrate 210, and a source region S and a drain region D may be disposed on both sides of the gate pattern 230 on the semiconductor substrate 210. As described above, each of the source and drain regions S and D may be a region doped with dopants or an inverted layer. The gate pattern 230 may comprise a control gate electrode 228a, a metal oxynitride layer 226, a dielectric layer 216, a charge storage layer 214 and a tunneling dielectric layer 212. The control gate electrode 228a may be disposed on the semiconductor substrate 210, and the charge storage layer 214 may be interposed between the control gate electrode 228a and the semiconductor substrate 210. The tunneling dielectric layer 212 may be interposed between the charge storage layer 214 and the semiconductor substrate 210, and the metal oxynitride layer 226 may be interposed between the charge storage layer 214 and the control gate electrode 228a. The dielectric layer 216 may be interposed between the metal oxynitride layer 226 and the charge storage layer 214. The dielectric layer 216 and the metal oxynitride layer 226 which are interposed between the charge storage layer 214 and the control gate electrode 228a may comprise a blocking layer. The gate pattern 230, source region S and drain region D may comprise a memory cell. The memory cell may have nonvolatile characteristics, i.e., may retain its stored data even when its power supply is interrupted. As described above, in addition to the dielectric layer 216, a second dielectric layer may exist between the metal oxynitride layer 226 and the control gate pattern 228a.

The metal oxynitride layer 226 included in the blocking layer may have a higher dielectric constant than the dielectric layer 216. Accordingly, under the same thickness, the equivalent oxide thickness of the metal oxynitride layer 226 may be smaller than that of the dielectric layer 216. The metal oxynitride layer 226 makes it possible to achieve a blocking layer which is physically thick while having a small equivalent oxide thickness. As a result, leakage of charges stored in the charge storage layer 214 to the control gate pattern 228a may be minimized, and data retention characteristics of the memory cell and reliability of data may be improved.

In addition, as described above, the metal oxynitride layer 226 may comprise a lower portion 222 including a nitrogen peak region. Accordingly, metal atoms within the metal oxynitride layer 226 may be prevented from diffusing and/or migrating to the external material layer. Elements within the external material layer may also be prevented from diffusing and/or migrating to the metal oxynitride layer 226. The external material layer may be the dielectric layer 216, either one of which is in contact with the metal oxynitride layer 226. Alternatively, in the case that a second metal nitride layer is additionally formed and the annealing process is carried out, the external material layer may be the gate control pattern 228a. As a result, the metal oxynitride layer 226 may have superior reliability. Accordingly, the memory cell employing the metal oxynitride layer 226 may also have superior reliability.

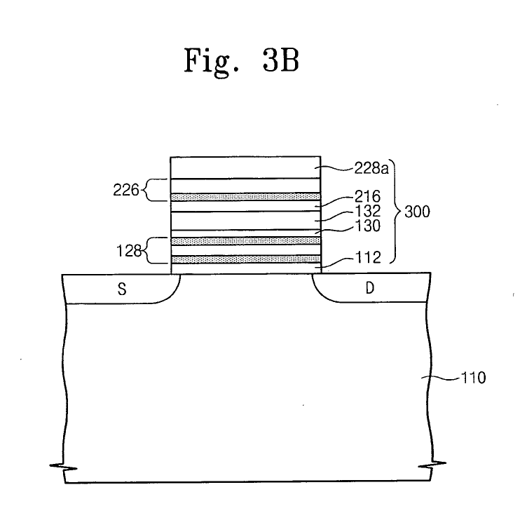

FIG. 3A is a cross-sectional view illustrating a method of fabricating a semiconductor device according to another exemplary embodiment of the present inventive concept. FIG. 3B is a cross-sectional view illustrating a semiconductor device according to this other exemplary embodiment of the present inventive concept.

Referring to FIG. 3A, according to the method described in connection with FIGS. 1A through 1C, a first dielectric layer 112, a first metal oxynitride layer 128 and a second dielectric layer 130 may be formed on a semiconductor substrate 110. As described above, after stacking a first metal nitride, a metal oxide and a second metal nitride, the first metal oxynitride layer 128 may be formed by annealing the stacked layers. Alternatively, either of the first or the second metal nitride can be omitted and the heat-treatment can be carried out. A charge storage layer 132 may be formed on the second dielectric layer 130.

According to the method described above in connection with FIG. 1D, the charge storage layer 132 may be formed as a charge trap layer or a floating gate layer. In addition, according to the method described above in connection with FIGS. 2C though 2E, a third dielectric layer 216, a second metal oxynitride layer 226 and a control gate conductive layer 228 may be formed on the charge storage layer 132. As described above, after stacking a metal nitride and a metal oxide, the second metal oxynitride layer 226 may be formed by annealing the stacked layers. Alternatively, the annealing process may be performed after additionally forming an additional metal nitride layer on the metal oxide layer. According to the method described above in connection with FIG. 1E and/or FIG. 2E, a gate pattern 300 may be formed through patterning, and a source region S and a drain region D may be formed.

According to another embodiment of the present inventive concept, at least one of the first, second, third dielectric layers 112, 130, and 216 may be omitted and an additional dielectric layer may be formed on the second metal nitride 226.

Next, a semiconductor device according to other exemplary embodiments of the present inventive concept will be described with reference to FIG. 3B.

Referring FIG. 3B, a gate pattern 300 may be disposed on a semiconductor substrate 110, and a source region S and a drain region D may be disposed on both sides of the gate pattern 300 on the semiconductor substrate 110. The gate pattern 300 may comprise a first dielectric layer 112, a first metal oxynitride layer 128, a second dielectric layer 130, a charge storage layer 132, a third dielectric layer 216, a second metal oxynitride layer 226 and a control gate electrode 228a. The control gate electrode 228a may be disposed on the semiconductor substrate 110, and the charge storage layer 132 may be interposed between the control gate electrode 228a and the semiconductor substrate 110. The first metal oxynitride layer 128 may be interposed between the charge storage layer 132 and the semiconductor substrate 110, and the second dielectric layer 226 may be interposed between the charge storage layer 132 and the control gate electrode 228a. The third dielectric layer 216 may be interposed between the second metal oxynitride layer 226 and the charge storage layer 132. The first dielectric layer 112, the first metal oxynitride layer 128 and the second dielectric layer 130 which are interposed between the charge storage layer 132 and the semiconductor substrate 110 may be included in a tunneling dielectric layer. The second metal oxynitride layer 226 and the third dielectric layer 216 which are interposed between the charge storage layer 132 and the control gate electrode 228a may be included in a blocking layer.

The gate pattern 300, source region S and drain region D may comprise a memory cell. As described above in connection with FIG. 1C, both the first and second dielectric layer 112 and 130 may exist or either of them may be omitted. As described above in connection with FIG. 2D, an additional metal nitride may be formed on the metal oxide (224 in FIG. 2D) so that the upper portion of the second metal nitride 226 may contain a nitrogen peak region, or as described above in connection with FIG. 2E above, an additional dielectric layer may be formed on the second metal oxynitride layer 226.

Because the first dielectric layer 112, the first metal oxynitride layer 128 and the second dielectric layer 130 included in the tunneling dielectric layer may have the same structure and characteristics as the tunneling dielectric layer shown in FIG. 1F, data retention characteristics of the memory cell, reliability of data, and program efficiency may be improved. Likewise, because the third dielectric layer 216 and the second metal oxynitride layer 226 included in the blocking layer may have the same structure and characteristics as the blocking layer shown in FIG. 1F, data retention characteristics and reliability of the memory cell may be improved.

Additionally, as described in connection with FIGS. 1F and 2F, the nitrogen peak regions residing in the metal oxynitride layers 128 and 226 may prevent elements within an external material layer from diffusing and/or migrating to the metal oxynitride layers 128 and 226. Likewise, the nitrogen peak regions may prevent metal atoms within the metal oxynitride layers 128 and 126 from diffusing and/or migrating to the external material layer.

As a result, the metal oxynitride layers 128 and 126 may have superior reliability, and therefore, a memory cell employing the metal oxynitride layer 128 and 226 may also have superior reliability.

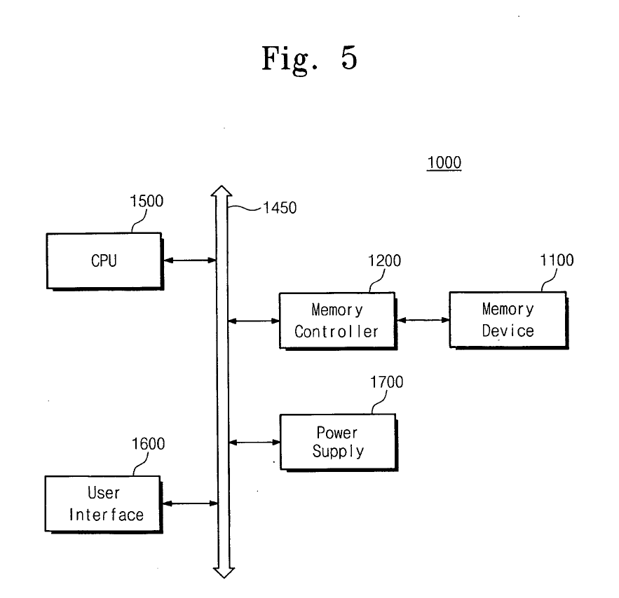

FIG. 5 is a block diagram of a memory system employing a semiconductor device according to exemplary embodiment of the present inventive concept.

Referring to FIG. 5, a memory system 1000 according an exemplary embodiment of the present inventive concept may comprise a memory device 1100, a memory controller 1200, a central processing unit (CPU) 1500 electrically connected to a system bus 1450, a user interface 1600, and a power supply 1700. The memory device 1100 may comprise at least one of the semiconductor devices described in connection with the above embodiments (FIGS. 1A through 1F, FIGS. 2A through 2F and FIGS. 3A through 3B).

The data provided through the user interface 1600 or processed by the CPU 1500 may be stored in the memory device 1100 by way of the memory controller 1200. The memory device 1100 may include a solid-state drive/disk (SSD). In such a case, writing speed of the memory system 1000 will be remarkably improved. Embodiments of the present inventive concept may be applied to the memory device 1100, the memory controller 1200, and the CPU 1500.

Although not illustrated in the figure, it will be appreciated by those skilled in the art that the memory system 1000 according to exemplary embodiments of the present inventive concept may further comprise an application chipset, a camera image processor, and/or a mobile DRAM.

Further, the memory system 1000 according to exemplary embodiments of the present inventive concept may be applicable to a PDA, a portable computer, a web tablet, a wireless phone, a mobile handset, a digital music player, a memory card, or any device that is capable of transmitting and/or receiving information wirelessly. Many modifications are possible in the example embodiments without materially departing from the novel teachings and advantages of the present inventive concept.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present invention. Accordingly, all such modifications are intended to be included within the scope of the present inventive concept as defined in the claims. Therefore, it is to be understood that the foregoing is illustrative of various exemplary embodiments and is not to be construed as limited to the specific exemplary embodiments described, and that modifications to the described exemplary embodiments, as well as other exemplary embodiments, are intended to be included within the scope of the appended claims.

1. A method for fabricating a semiconductor device, comprising:
forming a metal nitride layer and a metal oxide layer on a semiconductor substrate to be in contact with each other; and
annealing the substrate including the metal nitride layer and the metal oxide layer to form a metal oxynitride layer.

2. The method as set forth in claim 1, wherein forming a metal nitride layer and a metal oxide layer comprises:
forming the metal nitride layer on the semiconductor substrate; and
forming the metal oxide layer on the metal nitride layer.

3. The method as set forth in claim 2, further comprising before annealing the substrate:
forming a second metal nitride layer on the metal oxide layer,
wherein the metal oxynitride layer is formed by reacting the metal nitride layer, the metal oxide layer, and the second metal nitride layer with one another.

4. The method set forth in claim 1, wherein forming a metal nitride layer and a metal oxide layer comprises:
forming the metal oxide layer on the semiconductor substrate; and
forming the metal nitride layer on the metal oxide layer.

5. The method as set forth in claim 1, wherein the metal nitride layer Comprises metal elements of the same kind as that in the metal oxide layer.

6. The method as set forth in claim 1, further comprising forming a material layer on the semiconductor substrate to be in contact with one surface of the metal oxynitride layer.

7. The method as set forth in claim 6, wherein the metal oxynitride layer includes a nitrogen peak region adjacent to a surface that is in contact with the material layer.

8-10. (canceled)
